(19) United States
(12) Patent Application Publication
(10) Pub. No.: US 2017/0350752 A1
(43) Pub. Date: Dec. 7, 2017

(54) LIGHT EMITTING STRUCTURES AND SYSTEMS ON THE BASIS OF GROUP IV MATERIAL(S) FOR THE ULTRAVIOLET AND VISIBLE SPECTRAL RANGES

(71) Applicant: VENTSISLAV METODIEV LAVCHIEV, Gallneukirchen (AT)

(72) Inventor: VENTSISLAV METODIEV LAVCHIEV, Gallneukirchen (AT)

(21) Appl. No.: 15/169,921

(22) Filed: Jun. 1, 2016

(51) Int. Cl. G01J 1/42; G02B 1/02; G02B 5/00; H01L 33/38; H01L 33/34

(52) U.S. Cl. CPC G01J 1/42; H01L 33/38; H01L 33/343; G01J 1/429; G02B 5/008; G02B 1/02; H01L 33/34

(57) ABSTRACT

Material structures, systems and devices are disclosed. The material structures are active materials, which are able to emit UV/visible light under excitation by bias, by light beam or by electron beam. The input unit is a source of voltage/current or a source of light or a source of electron beam. The active unit is a material structure containing one or more layers of the described materials. The system may include a passive unit such as a ring resonator, a waveguide, coupler, grating or else. Additional units such as a control unit, readout unit or else may be also incorporated.

The distinguished characteristic of the present invention is that the UV or visible emission from the described structures cannot happen without the presence of at least one of the following quasi-particles: surface plasmons, surface plasmon polaritons, bulk plasmons and/or bulk plasmon polaritons. These quasi-particles assist the UV and the visible light emission.

### FIELD

The present disclosure generally relates to emission of light by highly crystalline materials, structures and devices fabricated and designed in a specific manner allowing for such light emission. The light emission, taking place in the ultraviolet UV and visible spectral ranges, is linked to bulk and surface plasmon polaritons in the materials and their interfaces, to the intraband and interband transitions of the electrons and holes in the valence band and conduction band, to the coupling between the surface plasmon polaritons and the particles generated in the intraband and interband transitions. The light emission is further linked to the oxygen related states on the Si and Ge interfaces with their oxides. The light emission, however, cannot happen without the presence of at least one of the following quasi-particles: surface plasmons, surface plasmon polaritons, bulk plasmons and/or bulk plasmon polaritons.

### BACKGROUND

Light emitters are material, structures or devices capable of emission of light when voltage or light of another wavelength or electron beam is applied to them. One type of light emitters is the emitters of visible light such as broadband lamps sources (in terms of spectral width of the emission). Another type of light emitter emits narrow spectral light such as light emitting diodes (LED), organic LED (OLED). Another type of light source is the laser, which is an emitter of coherent, narrow spectral light. Yet another type of emitters can emit light in ultra-violet or infrared spectral ranges.

The light emitters have a broad range of applications—for lighting, in TV screens, automobiles, data transmission, computers, radars, decoration, military, entertaining industry, night vision, sensor technologies, traffic control, in manufacturing or control in the manufacturing processes.

All existing to date light emitters are characterized by at least one of the following features—high power consumption, relatively high price, requirement of special technology for fabrication, use of relatively expensive materials for fabrication or non-compatibility to the silicon (Si)-based technology.

However, a light source based on a group-IV material—silicon (Si), germanium (Ge), tin (Sn), lead (Pb), carbon (C, for instance silicon carbide SiC), erbium (Er) or a combination of them—would bring enormous advantages for the Si-based industry and related industries.

The present invention is an efficient light emitter based on Si or Ge or combination of them or combination of these materials with their oxides or combination of them with antimony (Sb) or any doping.

### BRIEF DESCRIPTION OF THE DRAWINGS

The following is a brief description of the figures wherein the definitions “material structure” and “structure” are equal. All the materials are to be understood as highly crystalline or monocrystalline.

FIG. 1 is a diagram, illustrating a material structure composed of simply bulk monocrystalline Si.

FIG. 2A is a diagram illustrating a two-layer structure Ge/Si.

FIG. 2B is a diagram illustrating a two-layer structure SiO/Si.

FIG. 2C is a diagram illustrating a two-layer structure SiO₂/Si.

FIG. 3A is a diagram illustrating a two-layer structure Ge/SiO_{0.5}.

FIG. 3B is a diagram illustrating a two-layer structure Si/SiO_{0.5}.

FIG. 4A is a diagram illustrating a two-layer structure Ge/SiO.

FIG. 4B is a illustrating a two-layer structure Si/SiO.

FIG. 5A is a diagram illustrating a two-layer structure Ge/SiO₂.

FIG. 5B is a diagram illustrating a two-layer structure Si/SiO₂.

FIG. 6A is a diagram illustrating a two-layer structure GeO/Ge.

FIG. 6B is a diagram illustrating a two-layer structure GeO₂/Ge.

FIG. 7 is a diagram of a multilayer structure consisting of any combination of the above mentioned materials.

FIG. 8A is a diagram of a device based on one or more of the above mentioned materials. The diagram illustrates a device capable of light emission in UV, violet or visible spectral range when excitation of the structure by electrical mean i.e. bias is applied.

FIG. 8B is a diagram of a device based on one or more of the above mentioned materials. The diagram illustrates a device capable of light emission in UV, violet or visible spectral range when excitation of the structure by optical mean i.e. by light is applied.

FIG. 8C is a diagram of a device based on one or more of the above mentioned materials. The diagram illustrates a device capable of light emission in UV, violet or visible spectral range when excitation of the structure by electron beam is applied.

Optical excitation or excitation by bias can be applied to a multilayer structure (FIG. 7) in the similar way as in FIG. 8A or FIG. 8B.

FIG. 9 is a diagram illustrating a device, in which one of the above mentioned structures is placed in a resonator or a cavity for light amplification.

### DETAILED DESCRIPTION

The present invention will now be described with reference to the attached drawing figures, wherein like reference numerals are used to refer to like elements throughout, and wherein the illustrated structures and devices are not necessarily drawn to scale.

The light emitters in the present invention are based on a single-layer or bi-layer or a multi-layer material structure. The materials are monocrystalline, where applicable. The structure emits UV or visible light when excited electrically, optically or by an electron beam. The size, shape and composition of the materials forming the structure(s) can be varied or adjusted to form different devices, properties or features.

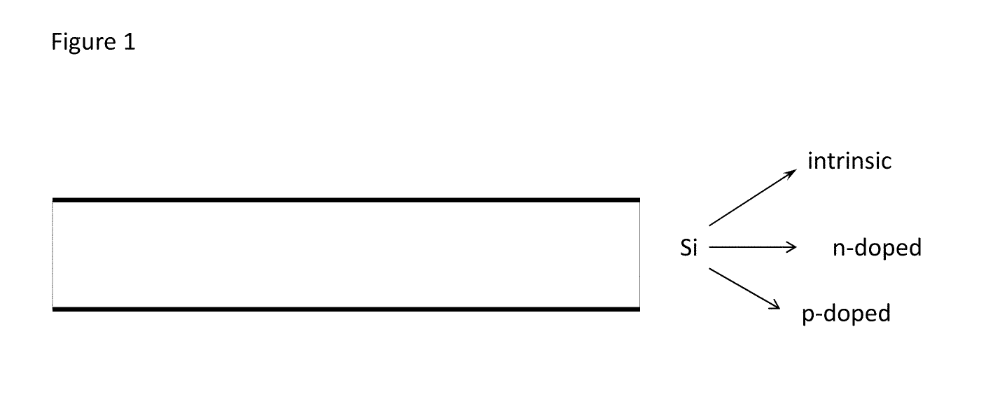

FIG. 1 is a diagram illustrating a structure from bulk monocrystalline Si. The Si can be intrinsic or doped. The structure is capable of UV/visible light emission under electrical or optical excitation or under excitation by an electron beam.

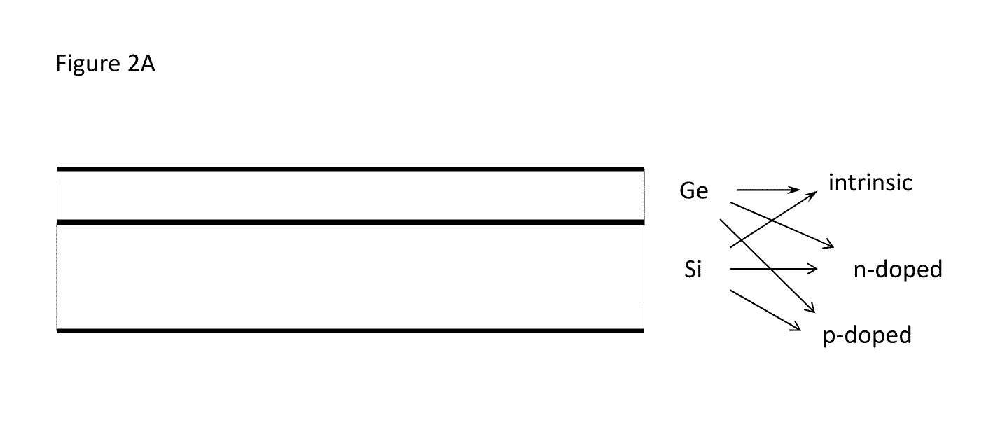

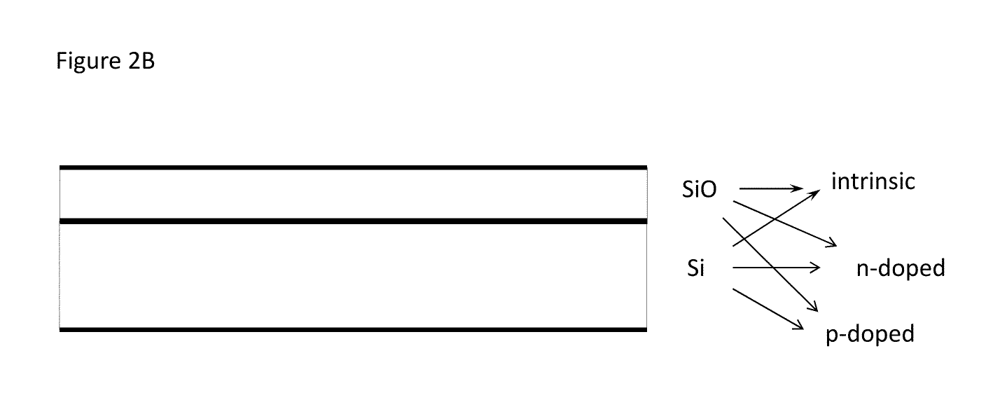

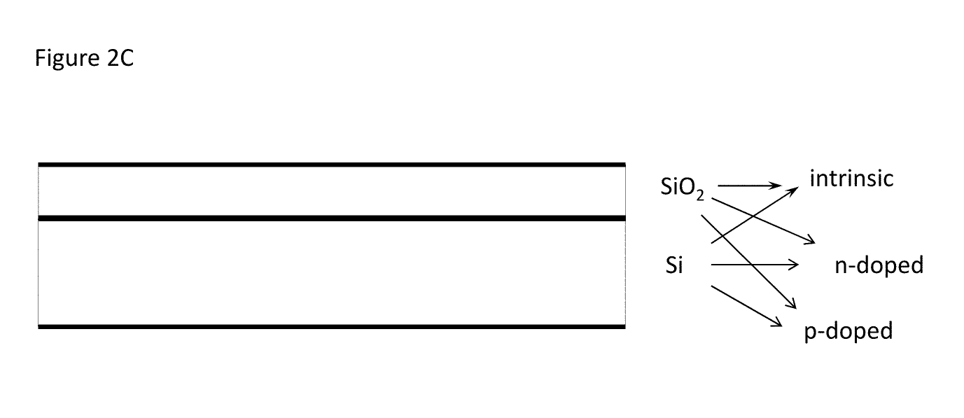

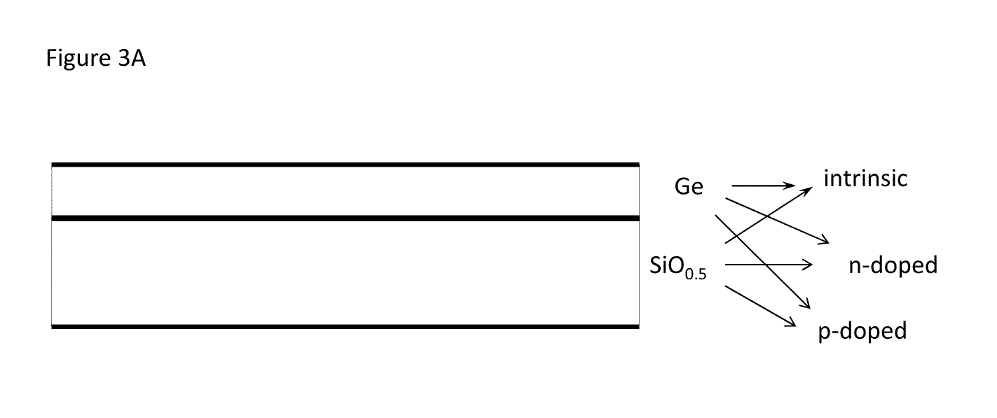

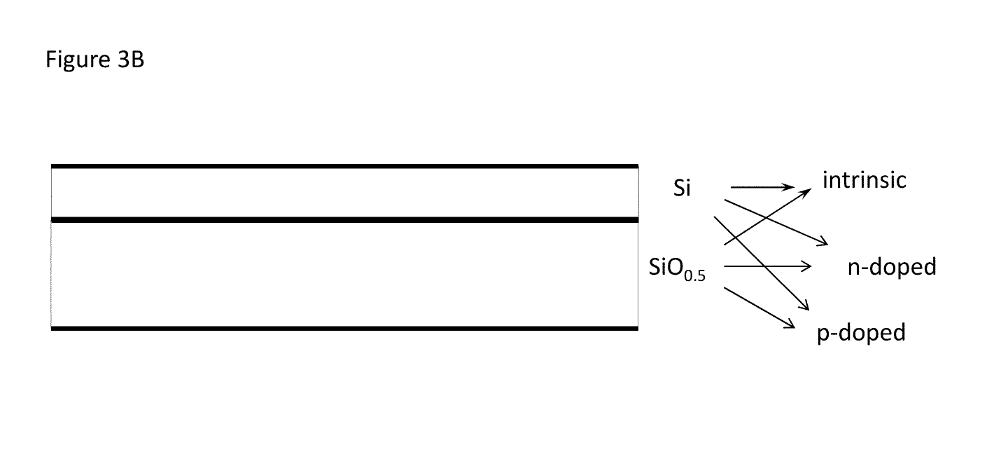

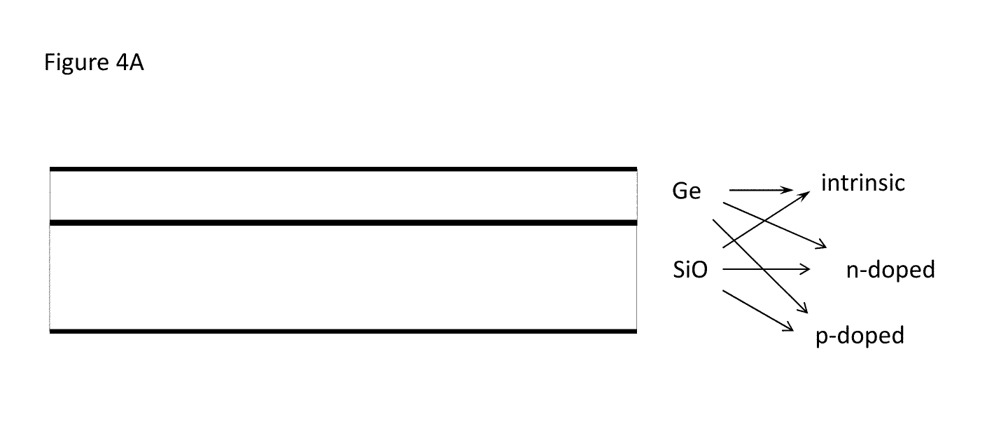

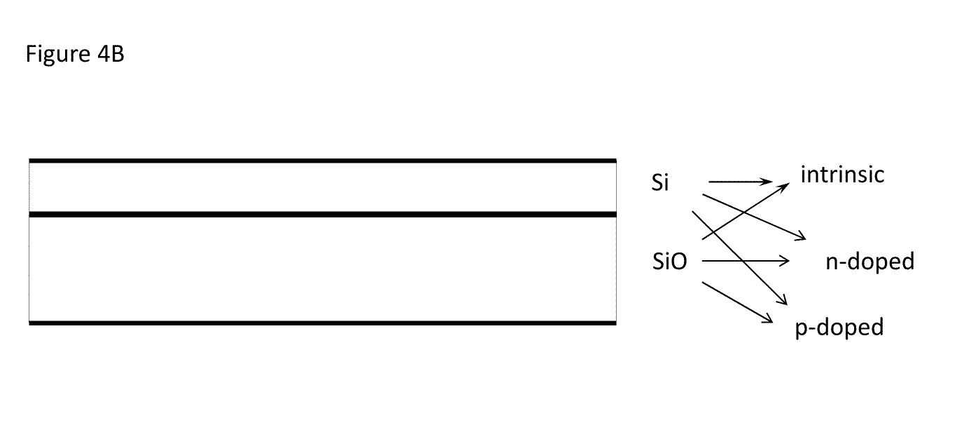

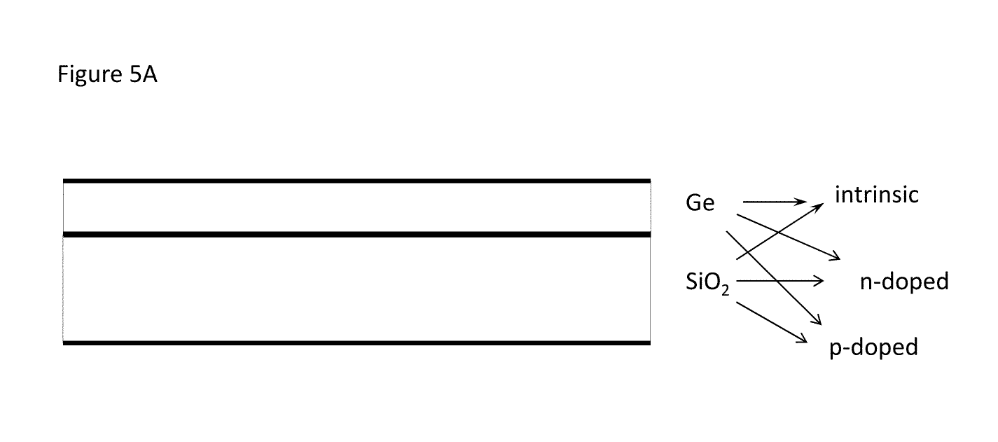

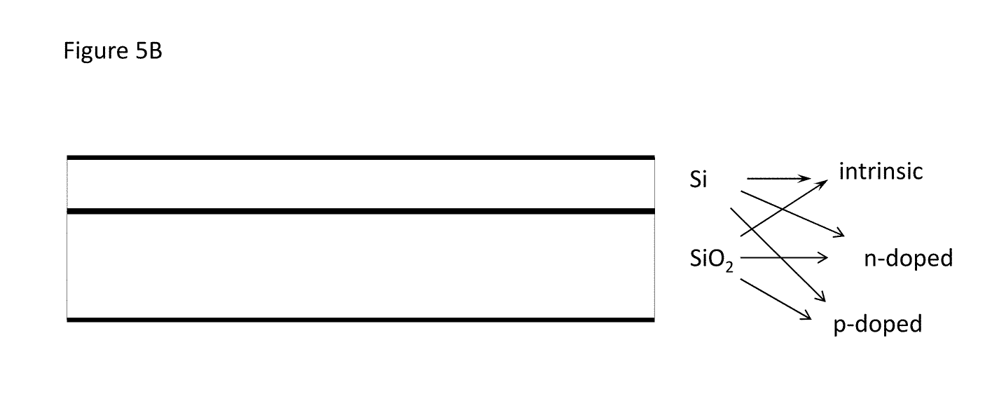

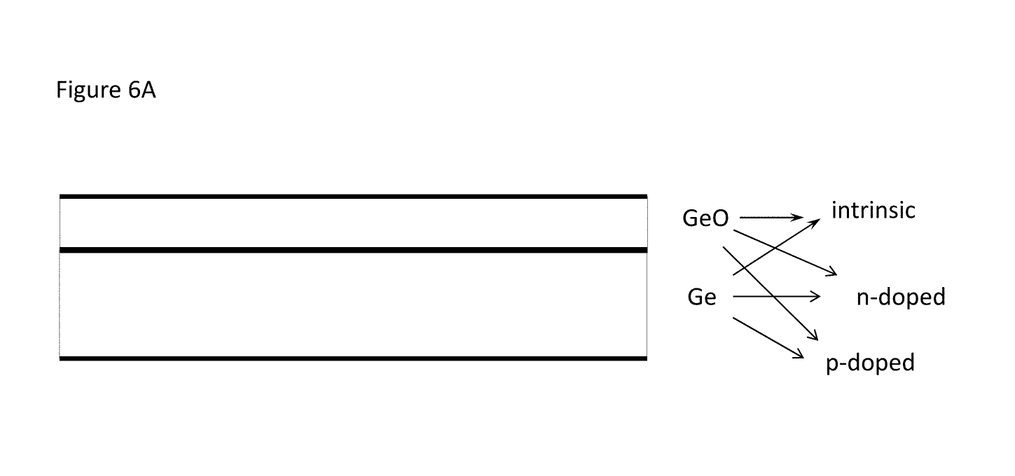

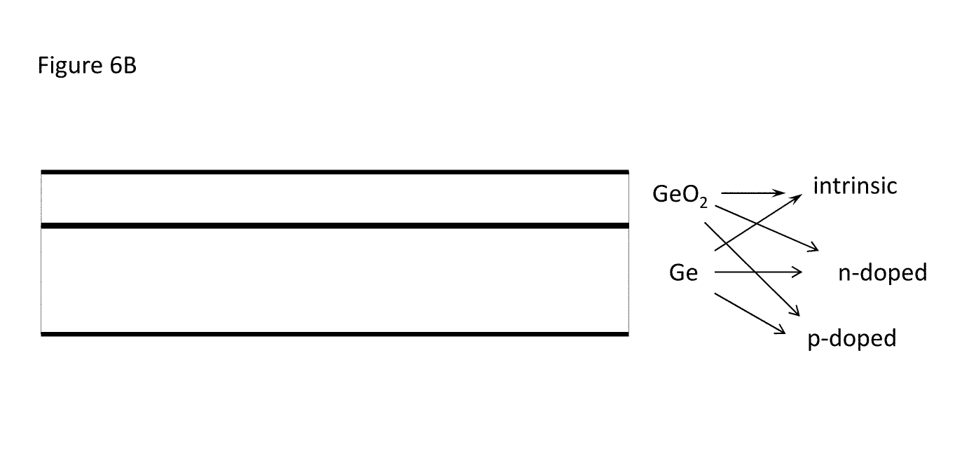

The bi-layer structures illustrated in FIG. 2A, FIG. 2B, FIG. 2C, FIG. 3A, FIG. 3B, FIG. 4A, FIG. 4B, FIG. 5A, FIG. 5B, FIG. 6A and FIG. 6B are capable of UV and/or visible light emission under electrical excitation (electroluminescence) or optical excitation (photoluminescence) or under excitation by an electron beam (cathodo-luminescence). The structures are composed of monocrystalline Si (undoped or doped), monocrystalline Ge (undoped or doped) and their oxides in combinations as depicted in the figures.

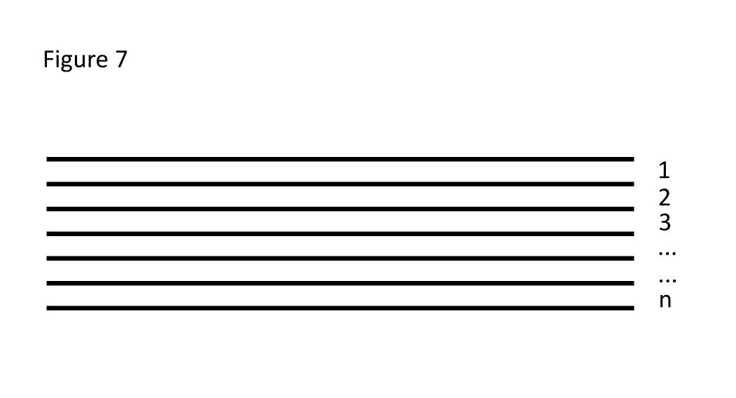

FIG. 7 is a diagram illustrating a multilayer structure composed of any combination of the following materials —Si, Ge, SiO, SiO₂, SiO_{0.5}, SiOₓ, where 0≦x≦1. Any layer of the multi-layer structure can be intrinsic or doped.

The doping can be p-type or n-type such as B (boron), Sb (antimony), P (phosphorous) or else. The doping is important for light emission even in the case of excitation of the structure(s) by optical beam or by electron beam. The doping changes the dielectric constant of the material, which in turn changes the spectral position of the plasmon and the plasmon polariton.

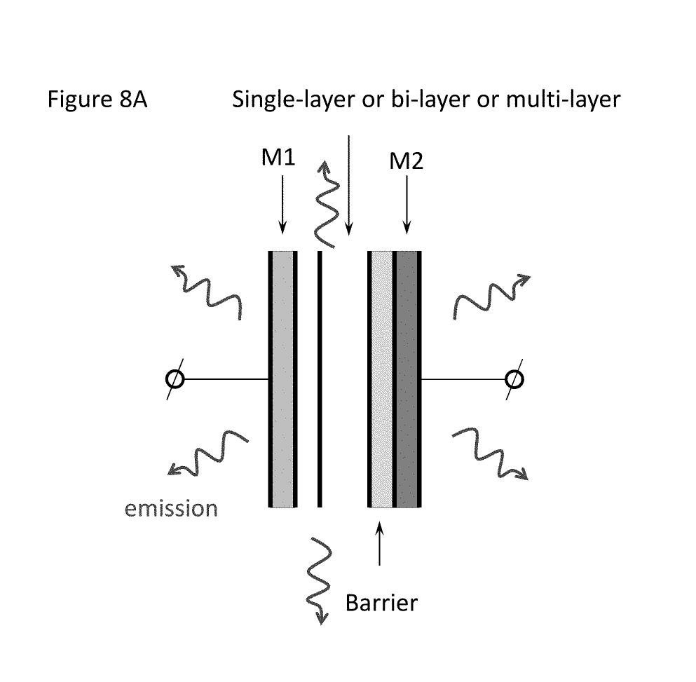

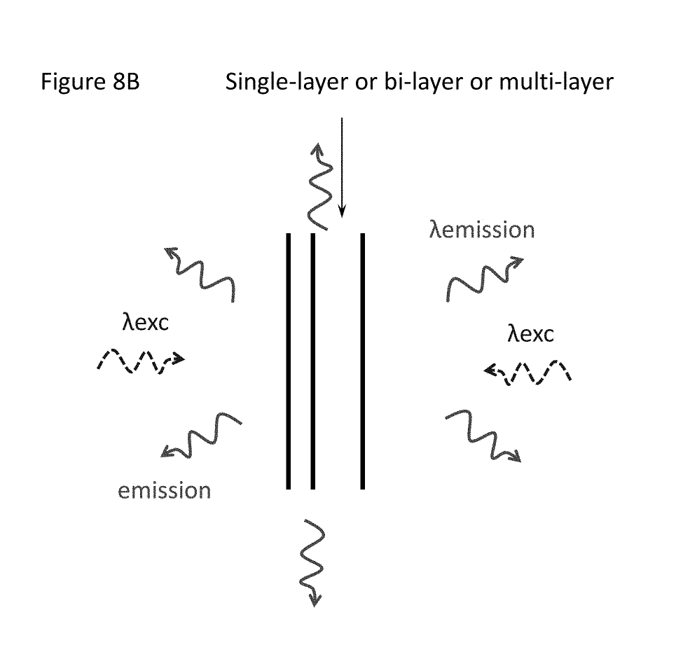

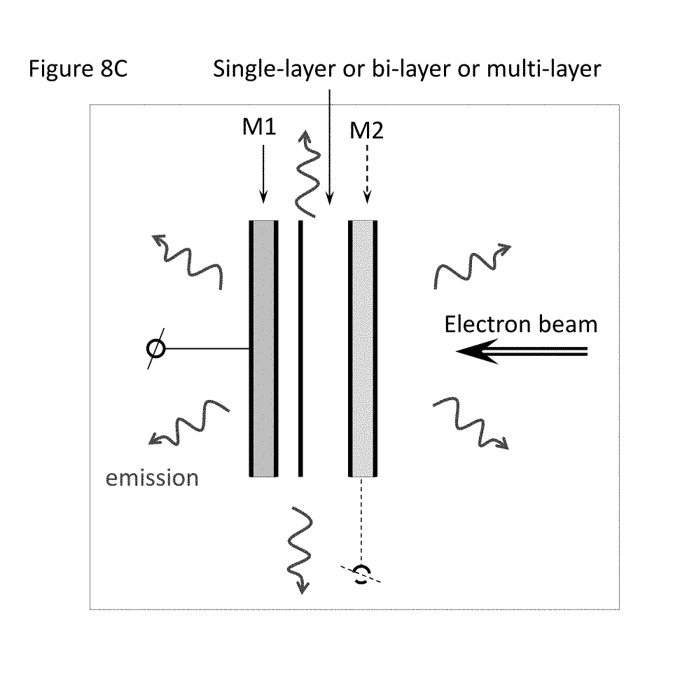

FIG. 8A is a diagram illustrating electrical excitation f a single-layer or bi-layer or multi-layer structure. The electrical excitation is done by means of application of bias. Electrode layers are deposited on both sides of the structure. The bias is applied to the electrodes. A barrier layer can be deposited between the electrode layer and the light emitting layer. In one example, the structure under electrical excitations is composed of the following layers ordered in a strict order: Cs (cesium) or Au (gold) electrode layer/emitting material/LaGdO₃ barrier layer/LaB₆ electrode layer. In another example, the structure under electrical excitations is composed of the following layers ordered in a strict order: Cs (cesium) or Au (gold) electrode layer/emitting material/LaBaO₃ barrier layer/LaB₆ electrode layer. The metals Cs and Au are selected due to their low work functions necessary in the electric excitation. In another example, other materials can be used as electrode layers and barrier layer. Unlike the conventional p-n, p-i-n or other junctions known to date, the presented structures in FIG. 7A generates light also by undoped materials and only when surface or/and bulk plasmons or plasmon polaritons are present (generated) in the material(s).

The generation of the surface plasmons, surface plasmon polaritons, bulk plasmons and/or bulk plasmon polaritons occurs simultaneously with the excitation bias/beam.

FIG. 8B is a sketch showing excitation of the structure by optical mean. In one example, the excitation source is a light source of a smaller wavelength as comparison to the wavelength of the emission from the structure (λ_{excitation}<λₑₘᵢₛₛᵢₒₙ). In another example, the excitation source is a broad band light source.

FIG. 8C is a sketch showing excitation of the structure by an electron beam. The structure is capable of light emission of UV and visible light under bombardment of the material (structure) by an electron beam. An electrode layer/structure can be deposited on the back surface or/and the front surface of the structure required for this type of excitation. In another example, the material structure is placed on a metal support playing the role of the electrode. Yet in another example, the electrode may be placed away from the material structure. The purpose of the electrode is to accelerate the electron beam (emitted from a cathode electrode) toward the material structure.

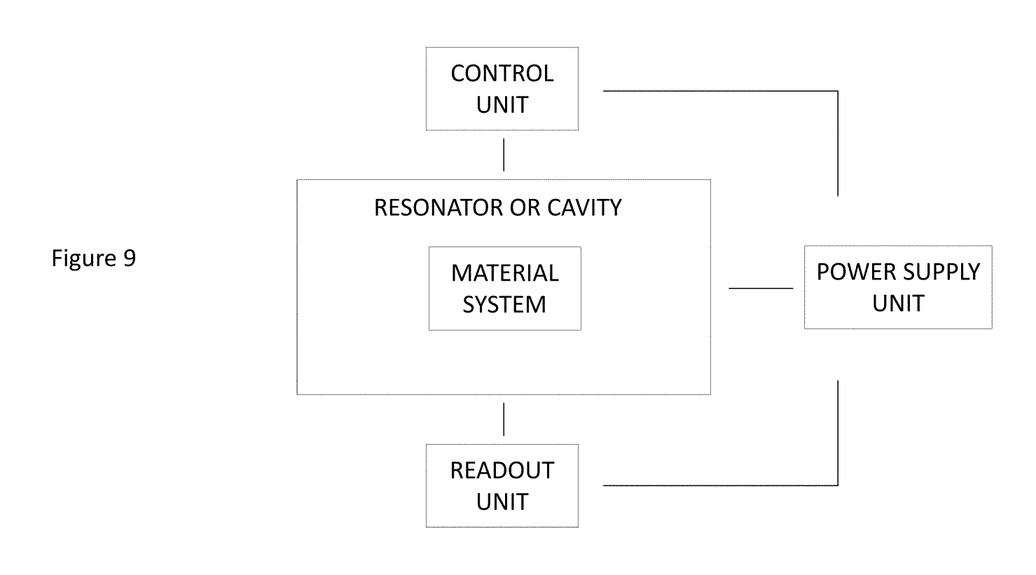

FIG. 9 illustrates a device, wherein the emitting structure named “material system” is placed in a resonator or a cavity. The purpose of the resonator/the cavity is to amplify the light emitted from the structure. The device also includes one or more additional units such as a control unit, a power supply unit and a readout unit. Additional unit may be the excitation source.

The material system in FIG. 8C and FIG. 9 may be placed in vacuum environment.

What is claimed is:

1. A material structure comprising one or more monocrystalline or annealed polycrystalline layers of the following structures able to emit ultra-violet or visible light:
Silicon (Si);
Germanium/Silicon (Ge/Si)
Silicon monoxide/Silicon (SiO/Si)
Silicon dioxide/Silicon (SiO₂/Si)
Germanium/Silicon oxide 0.5 (Ge/SiO_{0.5})
Silicon/Silicon oxide 0.5 (Si/SiO_{0.5})
Germanium/Silicon monoxide (Ge/SiO)
Silicon/Silicon monoxide (Si/SiO)
Germanium/Silicon dioxide (Ge/SiO₂)
Silicon/Silicon dioxide (Si/SiO₂)
Germanium oxide/Germanium (GeO/Ge)
Germanium dioxide/Germanium (GeO₂/Ge)
Any phase of the oxide SiOx in interface with Si or Ge, where 0≦x≦1
Any phase of the oxide GeOx in interface with Si or Ge, where 0≦x≦1

2. A material system including one or more layers/bi-layers of claim 1 in combination with metal layers or metal structures and barrier layers for electrical excitation.
The metal layer or structure can be on one side of the material system or on both sides of the material system and serves as an electrode.
The barrier layer is a layer, usually a dielectric or semiconductor material, building a band offset with the neighbouring metal layer and the layer of the material of claim 1.

3. A system comprising:
A source unit which:
Can supply voltage to the active unit;
Can supply current to the active unit;
An active unit containing one or more layers of the materials of claim 1 configured to emit light in the UV or visible spectral range depending upon the material, its doping and depending on the interface it forms with another layer;
The system may also include
A detector unit which detects the emitted UV or visible light
A passive unit, which captures the light from the active unit and makes use of it or guides the emitted light to the detector unit;

4. A system comprising:
A light source unit which:
Supplies excitation light with a broad band spectrum partially containing UV light;
Supplies excitation light of narrow band such as light emitting diode (LED) or a laser diode or a laser of another type;
An active unit containing one or more layers of the materials of claim 1 configured to emit light in the UV or visible spectral range depending upon the material, its doping and depending on the interface it forms with another layer;
The system may also include
A detector unit which detects the emitted UV or visible light
A passive unit, which captures the light from the active unit and makes use of it or guides the emitted light to the detector unit;

5. A system comprising:
A source unit which:
Supplies an electron beam for excitation of the structure;
An active unit containing one or more layers of the materials of claim 1 configured to emit light in the UV or visible spectral range depending upon the material, its doping and depending on the interface it forms with another layer;
The system may also include
A detector unit which detects the emitted UV or visible light
A passive unit, which captures the light from the active unit and makes use of it or guides the emitted light to the detector unit;

6. The system of claim 1, 2, 3 or 4 further comprising a resonator or a cavity to amplify the emitted light. The device may include one or more units from the following: a power supply unit, a control unit and a readout unit.

7. The system of claims 1 through 6 wherein the system may be incorporated in a vacuum environment.

8. The light emission occurs with the assistance of one or more of the following quasi-particles: surface plasmons, surface plasmon polaritons, bulk plasmons and/or bulk plasmon polaritons.
